(19) United States
(12) Patent Application Publication
(10) Pub. No.: US 2026/0182044 A1
(43) Pub. Date: Jun. 25, 2026

(54) SEMICONDUCTOR CHIP

(71) Applicant: SUMITOMO ELECTRIC INDUSTRIES, LTD., Osaka (JP)

(72) Inventors: Takeyoshi MASUDA, Osaka (JP); Yu SAITOH, Osaka (JP)

(21) Appl. No.: 18/843,507

(22) PCT Filed: Dec. 19, 2022
(86) PCT No.: PCT/JP2022/046591

§ 371 Date: Sep. 3, 2024

(30) Foreign Application Priority Data
May 19, 2022 (JP) 2022-082047

(51) Int. Cl. H10D 89/00

(52) U.S. Cl. CPC H10D 89/213

(57) ABSTRACT

A semiconductor chip (1) includes a plurality of transistor cells (100) arranged side by side along a first direction (Y). The transistor cells include a first semiconductor region (17) that extends along a second direction (X) orthogonal to the first direction and is of a first conductive type. The first semiconductor region is arranged such that a mutual inductance generated between: the first semiconductor region of one transistor cell of the transistor cells; and the first semiconductor region of another transistor cell of the transistor cells is a negative value, the one transistor cell and the another transistor cell being next to each other.

### TECHNICAL FIELD

The present disclosure relates to semiconductor chips.

### BACKGROUND ART

The present application claims priority to Japanese Patent Application No. 2022-082047, filed on May 19, 2022, and the entire contents of this Japanese patent application are incorporated herein by reference.

Semiconductor chips including a plurality of transistor cells arranged in parallel are known (see, for example, Patent Literature 1).

### CITATION LIST

### Patent Literature

Patent Literature 1: Japanese Laid-Open Patent Application No. 2012-23291

### SUMMARY OF THE INVENTION

A semiconductor chip of the present disclosure includes a plurality of transistor cells arranged side by side along a first direction. The transistor cells include a first semiconductor region that extends along a second direction orthogonal to the first direction and is of a first conductive type. The first semiconductor region is arranged such that a mutual inductance generated between: the first semiconductor region of one transistor cell of the transistor cells; and the first semiconductor region of another transistor cell of the transistor cells is a negative value, the one transistor cell and the another transistor cell being next to each other.

### BRIEF DESCRIPTION OF THE DRAWINGS

FIG. 1 is a circuit diagram illustrating a semiconductor chip according to an embodiment.

FIG. 2 is a cross-sectional perspective illustrating the semiconductor chip according to the embodiment.

FIG. 3 is a view illustrating configurations of an electric field relaxation region and a connection region in the semiconductor chip according to the embodiment.

FIG. 4 is a view illustrating configurations of a contact region and the connection region in the semiconductor chip according to the embodiment.

FIG. 5 is a cross-sectional view illustrating the semiconductor chip according to the embodiment (part 1).

FIG. 6 is a cross-sectional view illustrating the semiconductor chip according to the embodiment (part 2).

FIG. 7 is a cross-sectional view illustrating the semiconductor chip according to the embodiment (part 3).

### DETAILED DESCRIPTION OF THE DISCLOSURE

### Objects to be Solved by the Present Disclosure

In the existing semiconductor chips, a current of the same direction flows through p⁺ body layers of the transistor cells next to each other. Thus, the internal inductance of the p⁺ body layers may increase due to the mutual inductance generated between the p⁺ body layers next to each other.

It is an object of the present disclosure to provide a semiconductor chip in which the internal inductance can be reduced.

### Effects of the Present Disclosure

According to the present disclosure, it is possible to reduce the internal inductance.

Embodiments of the present disclosure will be described below.

### Description of Embodiments of the Present Disclosure

First, embodiments of the present disclosure will be listed and described. In the following description, the same or corresponding elements are provided with the same symbols, and the same description thereof is not repeated.

[1] A semiconductor chip according to one aspect of the present disclosure includes: a plurality of transistor cells arranged side by side along a first direction, the transistor cells including a first semiconductor region that extends along a second direction orthogonal to the first direction and is of a first conductive type, in which the first semiconductor region is arranged such that a mutual inductance generated between: the first semiconductor region of one transistor cell of the transistor cells; and the first semiconductor region of another transistor cell of the transistor cells is a negative value, the one transistor cell and the another transistor cell being next to each other. In this case, the mutual inductance works in a direction in which the self-inductance of the gate interconnects is reduced. Thus, the internal inductance of the first semiconductor regions can be reduced. Therefore, a semiconductor chip excellent in switching characteristics is obtained.
[2] In [1], the first semiconductor region may be arranged such that directions of currents flowing along the second direction are opposite between the first semiconductor region of the one transistor cell and the first semiconductor region of the another transistor cell. In this case, the mutual inductance is likely to be a negative value.
[3] In [1] or [2], the transistor cells may further include: a source electrode; and a second semiconductor region that is electrically connected to the first semiconductor region and the source electrode and is of the first conductive type, in which the second semiconductor region may be arranged such that the second semiconductor region of the one transistor cell may be arranged at a position different in the second direction from that of the second semiconductor region of the another transistor cell. In this case, currents of opposite directions are likely to flow through the first semiconductor regions next to each other.
[4] In [3], a plurality of second semiconductor regions each being the second semiconductor region may be arranged along the second direction, and positions in the second direction at which the second semiconductor regions are arranged in the one transistor cell may be an intermediate position between two second semiconductor regions of the second semiconductor regions of the another transistor cell, the two second semiconductor regions being next to each other in the second direction. In this case, currents of opposite directions are likely to flow through the first semiconductor regions next to each other.
[5] In [1] to [4], the first semiconductor regions may be an electric field relaxation region. In this case, the internal inductance of the electric field relaxation region can be reduced.
[6] In [1] to [5], the transistor cells may be a vertical transistor cell. In this case, both reduction in on-resistance and increase in breakdown voltage are likely to be achieved.

### Details of Embodiments of the Present Disclosure

Embodiments of the present disclosure will be described in detail below. However, the present disclosure is not limited thereto.

A semiconductor chip 1 according to an embodiment will be described.

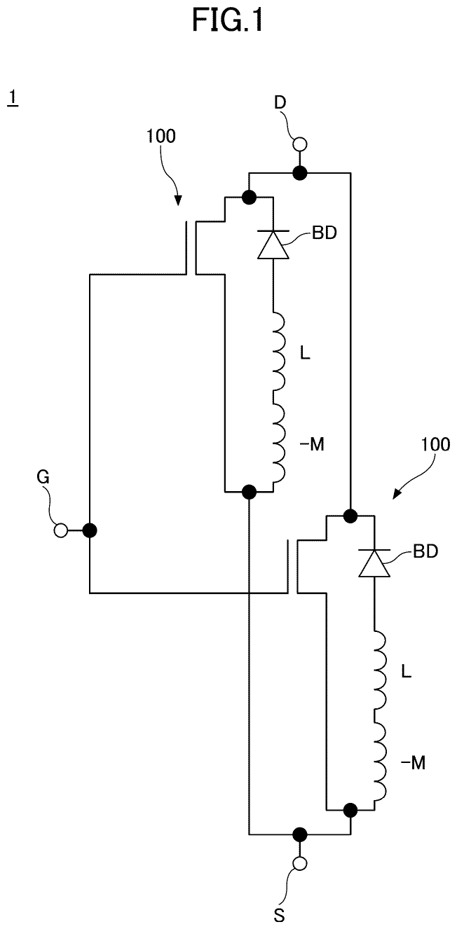

FIG. 1 is a circuit diagram illustrating the semiconductor chip 1 according to the embodiment. As illustrated in FIG. 1, the semiconductor chip 1 according to the embodiment includes a plurality of transistor cells 100.

The transistor cells 100 are electrically connected in parallel. The transistor cells 100 are electrically connected to a common gate terminal G, a common source terminal S, and a common drain terminal D. In this case, the transistor cells 100 can be mounted on the single semiconductor chip 1. In each of the transistor cells 100, a body diode BD is formed between the source terminal S and the drain terminal D. Each transistor cell 100 can have an internal inductance in a semiconductor region between the source terminal S and the drain terminal D. The internal inductance includes the mutual inductance between the semiconductor region of each transistor cell 100 and the semiconductor region of the transistor cell 100 next to this transistor cell 100.

Each semiconductor region is arranged such that the mutual inductance generated between this semiconductor region and the semiconductor region of the neighboring transistor cell 100 is a negative value. In this case, the mutual inductance works in the direction in which the self-inductance is reduced, and thus the internal inductance of the semiconductor region can be reduced. Therefore, the semiconductor chip 1 excellent in switching characteristics is obtained. Further, the reverse recovery characteristics of the body diode BD are improved, and a jump in the drain voltage can be suppressed.

For example, when the absolute value of the self-inductance of each semiconductor region is denoted by L and the absolute value of the mutual inductance between the semiconductor regions is denoted by M, the internal inductance of each semiconductor region is L-M. Therefore, the internal inductance of each semiconductor region can be reduced.

Meanwhile, when each semiconductor region is arranged such that the mutual inductance generated between this semiconductor region and the semiconductor region of the neighboring transistor cell 100 is a positive value, the internal inductance of each semiconductor region is L+M. Therefore, the internal inductance of each semiconductor region increases.

Each semiconductor region extends in a predetermined direction and is arranged, for example, such that the direction of the current flowing in the predetermined direction is opposite between this semiconductor region and the semiconductor region of the neighboring transistor cell 100. In this case, the mutual inductance having a negative value can be readily achieved.

Each semiconductor region may be an electric field relaxation region 17 described below. In this case, the internal inductance of the electric field relaxation region 17 can be reduced.

Next, a configuration of a field effect transistor that is an example of the semiconductor chip 1 according to the embodiment will be described.

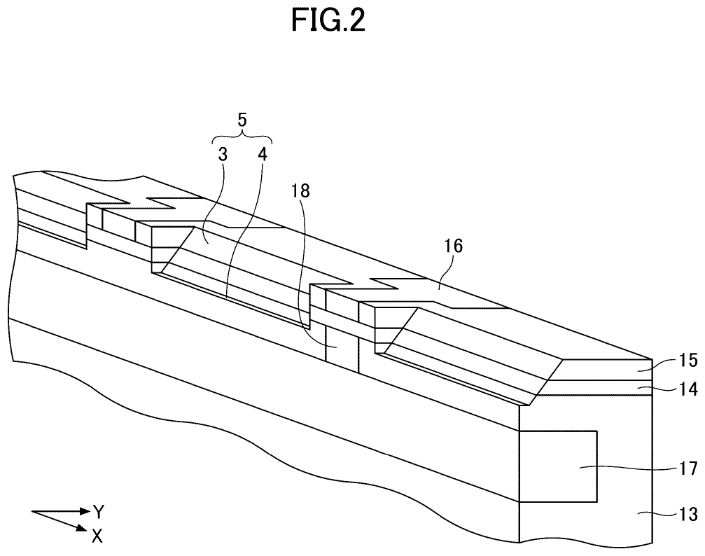

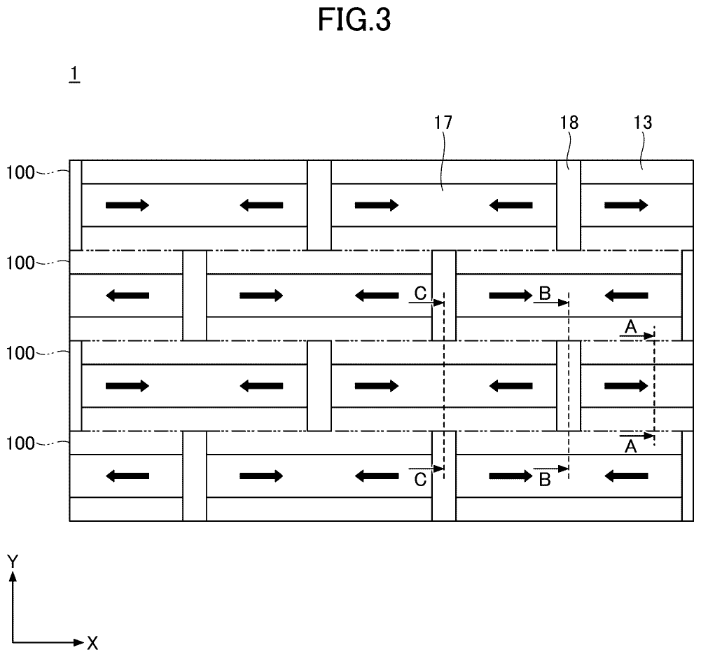

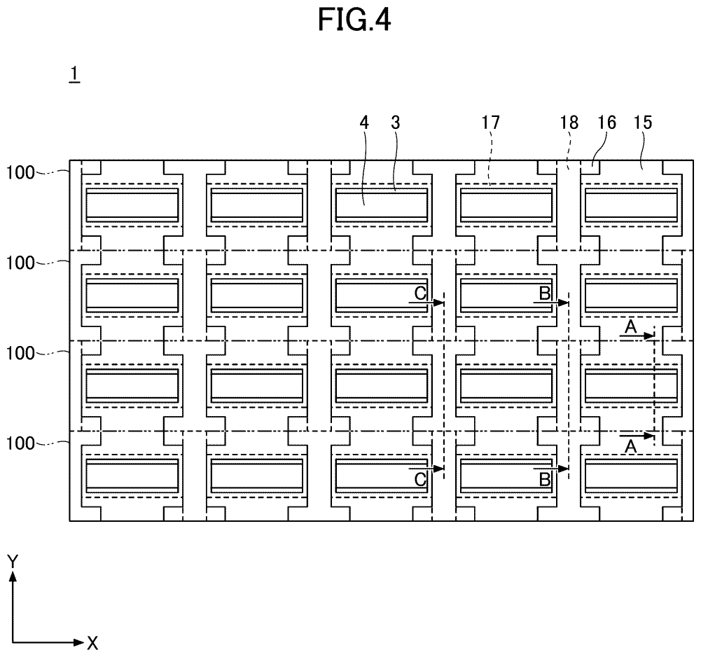

FIG. 2 is a cross-sectional perspective view illustrating the semiconductor chip 1 according to the embodiment. FIG. 2 omits illustration of a gate insulating film 21, a gate interconnect 22, an interlayer insulating film 23, and a source electrode 30, which will be described below. FIG. 3 is a cross-sectional view illustrating the configurations of the electric field relaxation region 17 and a connection region 18 in the semiconductor chip 1 according to the embodiment. FIG. 3 is a cross-sectional view taken along the lower end surface of the connection region 18 in FIG. 2. FIG. 4 is a cross-sectional view illustrating the configurations of a contact region 16 and the connection region 18 in the semiconductor chip 1 according to the embodiment. FIG. 4 is a cross-sectional view taken along the upper end surface of the contact region 16 in FIG. 2. As illustrated in FIGS. 3 and 4, the semiconductor chip 1 according to the embodiment includes the transistor cells 100.

The transistor cells 100 are arranged side by side along a Y-axis direction with an X-axis direction being a longitudinal direction. The Y-axis direction is an example of the first direction, and the X-axis direction is an example of the second direction. Each transistor cell 100 is, for example, a vertical transistor cell having a trench gate structure. Each transistor cell 100 may be a vertical transistor cell having a planar gate structure. When each transistor cell 100 is a vertical transistor cell, both reduction in on-resistance and increase in breakdown voltage are likely to be achieved.

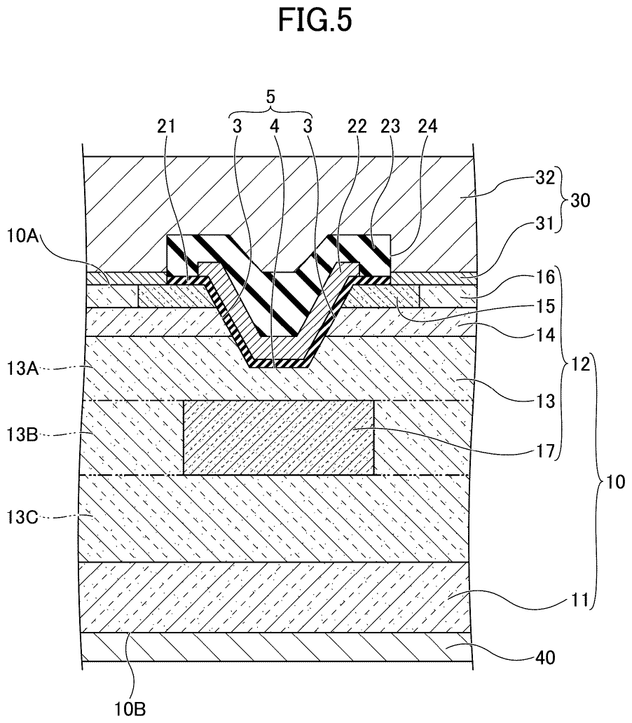

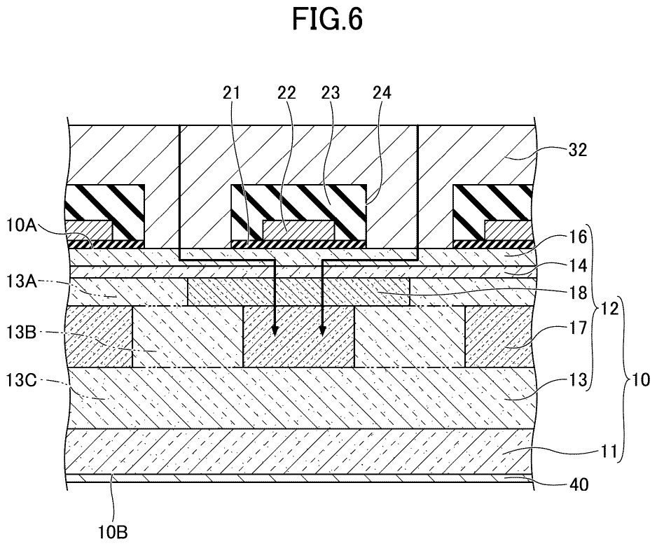

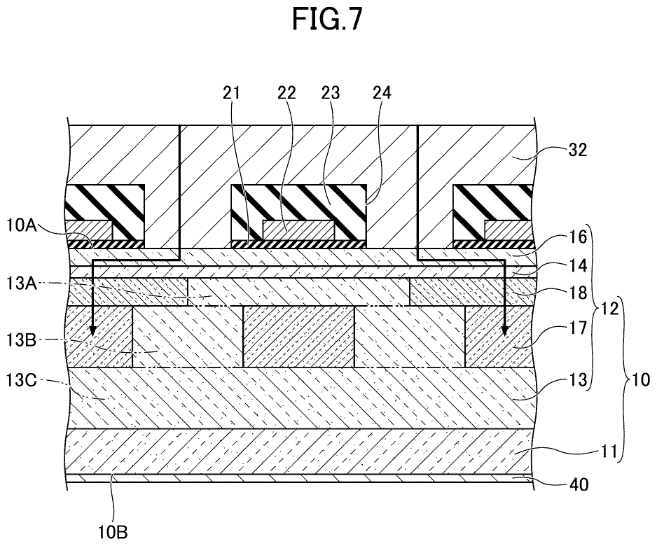

FIGS. 5 to 7 are cross-sectional views illustrating the semiconductor chip 1 according to the embodiment. FIG. 5 is a cross-sectional view taken along line A-A in FIGS. 3 and 4. FIG. 6 is a cross-sectional view taken along line B-B in FIGS. 3 and 4. FIG. 7 is a cross-sectional view taken along line C-C in FIGS. 3 and 4.

As illustrated in FIGS. 5 to 7, the semiconductor chip 1 according to the embodiment mainly includes a silicon carbide substrate 10, the gate insulating film 21, the gate interconnect 22, the interlayer insulating film 23, the source electrode 30, and a drain electrode 40.

The silicon carbide substrate 10 is an example of the semiconductor substrate. When the silicon carbide substrate 10 is used, an excellent breakdown voltage is likely to be obtained. The silicon carbide substrate 10 includes: a silicon carbide single crystal substrate 11; and a silicon carbide epitaxial layer 12 on the silicon carbide single crystal substrate 11. The silicon carbide substrate 10 includes a first main surface 10A and a second main surface 10B opposite to the first main surface 10A. The silicon carbide epitaxial layer 12 forms the first main surface 10A, and the silicon carbide single crystal substrate 11 forms the second main surface 10B. The silicon carbide single crystal substrate 11 and the silicon carbide epitaxial layer 12 are formed of, for example, hexagonal silicon carbide of polytype 4H. The silicon carbide single crystal substrate 11 includes an n-type dopant, such as nitrogen (N) or the like, and is of an n-type conductive type. The transistor cells 100 are formed on the silicon carbide substrate 10.

The silicon carbide epitaxial layer 12 mainly includes a drift region 13, a body region 14, a source region 15, the contact region 16, the electric field relaxation region 17, and the connection region 18.

The drift region 13 includes an n-type dopant, such as nitrogen, phosphorus (P), or the like, and is of an n-type conductive type. The drift region 13 includes a first region 13A, a second region 13B, and a third region 13C.

The body region 14 is provided on the drift region 13. The body region 14 includes a p-type dopant, such as aluminum (Al) or the like, and is of a p-type conductive type.

The source region 15 is provided on the body region 14. The source region 15 includes an n-type dopant, such as nitrogen, phosphorus, or the like, and is of an n-type conductive type. The source region 15 is separated from the drift region 13 by the body region 14. The source region 15 forms the first main surface 10A.

The contact region 16 includes a p-type dopant, such as aluminum or the like, and is of a p-type conductive type. The contact region 16 penetrates the source region 15 and contacts the body region 14. The contact region 16 forms the first main surface 10A. The effective concentration of the p-type dopant in the contact region 16 is, for example, 1×10¹⁸ cm⁻³ or higher and 2×10²⁰ cm⁻³ or lower.

The first main surface 10A is provided with a gate trench 5 defined by a side surface 3 and a bottom surface 4. The side surface 3 penetrates the source region 15 and the body region 14, and reaches the drift region 13. The side surface 3 may be, for example, a surface inclined with respect to the second main surface 10B or a surface perpendicular to the second main surface 10B. The bottom surface 4 is continuous with the side surface 3. The bottom surface 4 is in the drift region 13. The bottom surface 4 is, for example, a flat plane parallel to the second main surface 10B. The gate trench 5 is provided, for example, in the form of an island along the X-axis direction. In a plan view from a direction perpendicular to the first main surface 10A, the gate trenches 5 are provided at regular intervals in the Y-axis direction.

The electric field relaxation region 17 includes a p-type dopant, such as aluminum or the like, and is of a p-type conductive type. The electric field relaxation region 17 extends along the X-axis direction. The electric field relaxation region 17 is somewhere between the body region 14 and the second main surface 10B. In a plan view from the direction perpendicular to the first main surface 10A, the electric field relaxation region 17 includes a portion overlapping the gate trench 5. The electric field relaxation region 17 reduces the concentration of the electric field on the gate insulating film 21 in contact with the bottom surface 4 upon application of a high voltage. In the direction perpendicular to the second main surface 10B, the upper end surface of the electric field relaxation region 17 is separated from the bottom surface 4. The upper end surface of the electric field relaxation region 17 may include the bottom surface 4 of the gate trench 5. A part of the upper end surface of the electric field relaxation region 17 faces a part of the lower end surface of the body region 14. The electric field relaxation region 17 is electrically connected to the source electrode 30. In this case, the electric field relaxation region 17 becomes a source potential, and thus parasitic capacitance between the gate interconnect 22 and the drain electrode 40 can be reduced. Therefore, the switching speed is increased. The effective concentration of the p-type dopant in the electric field relaxation region 17 is, for example, 5×10¹⁷ cm⁻³ or higher and 5×10¹⁸ cm⁻³ or lower. The electric field relaxation region 17 is an example of the first semiconductor region.

The connection region 18 includes a p-type dopant, such as aluminum or the like, and is of a p-type conductive type. The connection region 18 penetrates the first region 13A and reaches the electric field relaxation region 17. The connection region 18 electrically connects the body region 14 and the electric field relaxation region 17. In this case, as indicated by the arrows in FIGS. 6 and 7, currents flow from the source electrode 30 to the electric field relaxation region 17 by passing through the contact region 16, the body region 14, and the connection region 18 in this order. The connection region 18 contacts the body region 14. The connection region 18 may be in contact with the contact region 16. The connection region 18 may be in contact with both of the body region 14 and the contact region 16. The connection region 18 is somewhere between the contact region 16 and the electric field relaxation region 17. The connection region 18 is closer to the second main surface 10B than is the contact region 16. The connection region 18 is closer to the first main surface 10A than is the electric field relaxation region 17. The connection regions 18 are arranged, for example, at regular intervals along the X-axis direction. The effective concentration of the p-type dopant in the connection region 18 may be substantially the same as that of the p-type dopant in the electric field relaxation region 17. The effective concentration of the p-type dopant in the connection region 18 is, for example, 5×10¹⁷ cm⁻³ or higher and 5×10¹⁸ cm⁻³ or lower. The connection region 18 is an example of the second semiconductor region.

The connection region 18 is arranged at a position different, in the X-axis direction, from that of the connection region 18 of the neighboring transistor cell 100. In this case, as indicated by the arrows in FIG. 3, currents of opposite directions are likely to flow through the electric field relaxation regions 17 next to each other.

The position in the X-axis direction at which the connection region 18 is arranged may be, for example, an intermediate position between the two connection regions 18 next to each other in the X-axis direction of the neighboring transistor cell 100. In this case, currents of opposite directions are likely to flow through the electric field relaxation regions 17 next to each other.

The first region 13A of the drift region 13 is somewhere between the body region 14 and the electric field relaxation region 17. The first region 13A is in contact with the body region 14 and the electric field relaxation region 17. The first region 13A is closer to the first main surface 10A than is the electric field relaxation region 17.

The second region 13B is closer to the second main surface 10B than is the first region 13A. The second region 13B is continuous with the first region 13A. The second region 13B is in contact with the electric field relaxation region 17 in a direction parallel to the second main surface 10B. The second region 13B and the electric field relaxation region 17 may be positioned in the same plane parallel to the second main surface 10B. The effective concentration of the n-type dopant in the second region 13B may be higher than that of the n-type dopant in the first region 13A.

The third region 13C is closer to the second main surface 10B than is the second region 13B. The third region 13C is continuous with the second region 13B. The third region 13C is in contact with the electric field relaxation region 17. The third region 13C is closer to the second main surface 10B than is the electric field relaxation region 17. The third region 13C may be between the second region 13B and the silicon carbide single crystal substrate 11. The third region 13C may be continuous with the silicon carbide single crystal substrate 11. The effective concentration of the n-type dopant in the third region 13C may be the same as that of the n-type dopant in the second region 13B.

The gate insulating film 21 is, for example, an oxide film. The gate insulating film 21 is formed of a material including silicon dioxide and the like. The gate insulating film 21 is in contact with the side surface 3 and the bottom surface 4. The gate insulating film 21 is in contact with the first region 13A at the bottom surface 4. The gate insulating film 21 is in contact with the source region 15, the body region 14, and the first region 13A at the side surface 3. The gate insulating film 21 may be in contact with the source region 15 at the first main surface 10A.

The gate interconnect 22 is provided on the gate insulating film 21. The gate interconnect 22 is formed of, for example, polysilicon including conductive impurities. The gate interconnect 22 is provided in the gate trench 5. A part of the gate interconnect 22 may be provided on the first main surface 10A.

The interlayer insulating film 23 covers the gate interconnect 22. The interlayer insulating film 23 is in contact with the gate interconnect 22 and the gate insulating film 21. The interlayer insulating film 23 is, for example, an oxide film. The interlayer insulating film 23 is formed of, for example, a material including silicon dioxide. The interlayer insulating film 23 electrically insulates the gate interconnect 22 and the source electrode 30 from each other. A part of the interlayer insulating film 23 may be provided in the gate trench 5.

Contact holes 24 are formed in the interlayer insulating film 23 and the gate insulating film 21. The contact holes 24 are provided at regular intervals in the Y-axis direction. In a plan view from the direction perpendicular to the first main surface 10A, the contact holes 24 are provided such that the gate trench 5 is positioned between the contact holes 24 next to each other in the Y-axis direction. The contact holes 24 extend along the X-axis direction. The source region 15 and the contact region 16 are exposed from the interlayer insulating film 23 and the gate insulating film 21 through the contact holes 24. The contact region 16 does not have to be continuous along the X-axis direction and can be formed periodically. A barrier metal film that covers the upper and side surfaces of the interlayer insulating film 23 and the side surface of the gate insulating film 21 may be formed.

The source electrode 30 is in contact with the first main surface 10A. The source electrode 30 includes a contact electrode 31 and a source interconnect 32.

The contact electrode 31 is in contact with the source region 15 and the contact region 16 at the first main surface 10A. The contact electrode 31 is formed of, for example, a material including nickel silicide (NiSi). The contact electrode 31 may be formed of a material including titanium, aluminum, and silicon. The contact electrode 31 is in an ohmic contact with the contact region 16.

The source interconnect 32 covers the upper and side surfaces of the interlayer insulating film 23 and the upper surface of the contact electrode 31. The source interconnect 32 is in contact with the contact electrode 31. The source interconnect 32 is formed of, for example, a material including aluminum.

The drain electrode 40 is in contact with the second main surface 10B. The drain electrode 40 is in contact with the silicon carbide single crystal substrate 11 at the second main surface 10B. The drain electrode 40 is electrically connected to the drift region 13. The drain electrode 40 is formed of, for example, a material including nickel silicide. The drain electrode 40 may be formed of a material including titanium, aluminum, and silicon. The drain electrode 40 is in an ohmic contact with the silicon carbide single crystal substrate 11.

Although the embodiments have been described in detail above, the present invention is not limited to the specific embodiments. Various modifications and changes are possible within the scope of the claims recited.

### REFERENCE SIGNS LIST

1 Semiconductor chip
3 Side surface
4 Bottom surface
5 Gate trench
10 Silicon carbide substrate
10A First main surface
10B Second main surface
11 Silicon carbide single crystal substrate
12 Silicon carbide epitaxial layer
13 Drift region
13A First region
13B Second region
13C Third region
14 Body region
15 Source region
16 Contact region
17 Electric field relaxation region
18 Connection region
21 Gate insulating film
22 Gate interconnect
23 Interlayer insulating film
24 Contact hole
30 Source electrode
31 Contact electrode
32 Source interconnect
40 Drain electrode
100 Transistor cell
BD Body diode
D Drain terminal
G Gate terminal
S Source terminal

1. A semiconductor chip, comprising:
a plurality of transistor cells arranged side by side along a first direction,
the transistor cells including
a first semiconductor region that extends along a second direction orthogonal to the first direction and is of a first conductive type, wherein
the first semiconductor region is arranged such that a mutual inductance generated between (i) the first semiconductor region of one transistor cell of the transistor cells, and (ii) the first semiconductor region of another transistor cell of the transistor cells, is a negative value; the one transistor cell and the another transistor cell being next to each other.

2. The semiconductor chip according to claim 1, wherein
the first semiconductor region is arranged such that directions of currents flowing along the second direction are opposite between the first semiconductor region of the one transistor cell and the first semiconductor region of the another transistor cell.

3. The semiconductor chip according to claim 1, wherein
the transistor cells further include:
a source electrode; and
a second semiconductor region that is electrically connected to the first semiconductor region and the source electrode and is of the first conductive type, wherein
the second semiconductor region is arranged such that the second semiconductor region of the one transistor cell is arranged at a position different in the second direction from that of the second semiconductor region of the another transistor cell.

4. The semiconductor chip according to claim 3, wherein
a plurality of second semiconductor regions each being the second semiconductor region are arranged along the second direction, and
positions in the second direction at which the second semiconductor regions are arranged in the one transistor cell are an intermediate position between two second semiconductor regions of the second semiconductor regions of the another transistor cell, the two second semiconductor regions being next to each other in the second direction.

5. The semiconductor chip according to claim 1, wherein
the first semiconductor regions are an electric field relaxation region.

6. The semiconductor chip according to claim 1, wherein
the transistor cells are a vertical transistor cell.

7. The semiconductor chip according to claim 2, wherein
the transistor cells are a vertical transistor cell.

8. The semiconductor chip according to claim 3, wherein
the transistor cells are a vertical transistor cell.

9. The semiconductor chip according to claim 4, wherein
the transistor cells are a vertical transistor cell.

10. The semiconductor chip according to claim 5, wherein
the transistor cells are a vertical transistor cell.
